(19) United States
(12) Patent Application Publication
(10) Pub. No.: US 2019/0011291 A1
(43) Pub. Date: Jan. 10, 2019

(54) REDUCING NOISE IN A CAPACITIVE SENSOR

(71) Applicant: Cirrus Logic International Semiconductor Ltd., Edinburgh (GB)

(72) Inventors: Vamsikrishna PARUPALLI, Austin, TX (US); Zhong YOU, Austin, TX (US); Gaurav AGARWAL, Austin, TX (US); Vikrant ARUMUGAM, Cedar Park, TX (US); Johann G. GABORIAU, Austin, TX (US); Nishant JAIN, Austin, TX (US)

(73) Assignee: Cirrus Logic International Semiconductor Ltd., Edinburgh (GB)

(21) Appl. No.: 15/926,276

(22) Filed: Mar. 20, 2018

Related U.S. Application Data
(60) Provisional application No. 62/529,698, filed on Jul. 7, 2017.

(51) Int. Cl. G01D 5/24; G01R 27/26; H04L 27/144; G01R 29/26

(52) U.S. Cl. CPC G01D 5/24; G01R 29/26; H04L 27/144; G01R 27/2605

(57) ABSTRACT

A method for measuring a capacitive sensor output may include applying an excitation signal to a capacitor of the capacitive sensor which causes generation of a modulated signal from a baseband signal, wherein the excitation signal is of a carrier frequency which is higher than frequency content of the baseband signal, demodulating the modulated signal to generate an output signal representative of a capacitance of the capacitor wherein the demodulating is based, at least in part, on the excitation signal, determining whether noise in the modulated signal is caused by interference at approximately the carrier frequency, and in response to determining noise in the modulated signal is caused by interference at approximately the carrier frequency, modifying the carrier frequency to another frequency to reduce noise caused in the modulated signal by the interference.

### CROSS-REFERENCE AND RELATED APPLICATION

The present disclosure claims benefit of U.S. Provisional Patent Application Ser. No. 62/529,698, filed Jul. 7, 2017, which is incorporated by reference herein in its entirety.

### FIELD OF DISCLOSURE

The present disclosure relates in general to measuring capacitance, and more specifically, to systems and methods for measuring capacitance using a capacitance to voltage converter in a noisy environment.

### BACKGROUND

In many electrical and electronic systems, it may be desirable to measure a capacitance within a circuit in order to take action responsive to the measured capacitance. For example, a capacitive sensor used in an audio speaker may be used to sense a position of a transducer diaphragm of the audio speaker. The capacitance value of a capacitive sensor which changes responsive to an audio signal driven through the speaker may be measured by driving a carrier tone on one terminal of the speaker and sensing a modulated signal current on the other terminal.

One type of apparatus for measuring capacitance is known as a capacitance-to-digital converter, or “CDC,” which is capable of measuring a capacitance and generating a digital output signal indicative of a magnitude of the measured capacitance. A CDC-based capacitive sensor may operate in a noisy environment which can affect measurement sensitivity of a measurement, and thus, systems and methods for reducing or eliminating such noise may be desirable.

### SUMMARY

In accordance with the teachings of the present disclosure, certain disadvantages and problems associated with performance of existing capacitance-to-digital converters have been reduced or eliminated.

In accordance with embodiments of the present disclosure, a method for measuring a capacitive sensor output may include applying an excitation signal to a capacitor of the capacitive sensor which causes generation of a modulated signal from a baseband signal, wherein the excitation signal is of a carrier frequency which is higher than frequency content of the baseband signal, demodulating the modulated signal to generate an output signal representative of a capacitance of the capacitor wherein the demodulating is based, at least in part, on the excitation signal, determining whether noise in the modulated signal is caused by interference at approximately the carrier frequency, and in response to determining noise in the modulated signal is caused by interference at approximately the carrier frequency, modifying the carrier frequency to another frequency to reduce noise caused in the modulated signal by the interference.

In accordance with these and other embodiments of the present disclosure, an apparatus for measuring a capacitive sensor output may include an excitation source configured to apply an excitation signal to a capacitor of the capacitive sensor which causes generation of a modulated signal from a baseband signal, wherein the excitation signal is of a carrier frequency which is higher than frequency content of the baseband signal, a demodulator configured to demodulate the modulated signal to generate an output signal representative of a capacitance of the capacitor, wherein the demodulator is configured to demodulate based, at least in part, on the excitation signal, and a controller. The controller may be configured to determine whether noise in the modulated signal is caused by interference at approximately the carrier frequency and in response to determining noise in the modulated signal is caused by interference at approximately the carrier frequency, modify the carrier frequency to another frequency to reduce noise caused in the modulated signal by the interference.

Technical advantages of the present disclosure may be readily apparent to one having ordinary skill in the art from the figures, description and claims included herein. The objects and advantages of the embodiments will be realized and achieved at least by the elements, features, and combinations particularly pointed out in the claims.

It is to be understood that both the foregoing general description and the following detailed description are explanatory examples and are not restrictive of the claims set forth in this disclosure.

### BRIEF DESCRIPTION OF THE DRAWINGS

A more complete understanding of the example, present embodiments and certain advantages thereof may be acquired by referring to the following description taken in conjunction with the accompanying drawings, in which like reference numbers indicate like features, and wherein:

FIG. 1 is a block diagram of selected components of an example capacitance-sensing circuit wherein carrier demodulation is implemented in an analog domain, in accordance with embodiments of the present disclosure;

FIG. 2 is a block diagram of selected components of an example capacitance-sensing circuit wherein carrier demodulation is implemented in the digital domain, in accordance with embodiments of the present disclosure; and

FIG. 3 is a flow chart of an example method for reducing noise in a capacitive sensor, in accordance with embodiments of the present disclosure.

### DETAILED DESCRIPTION

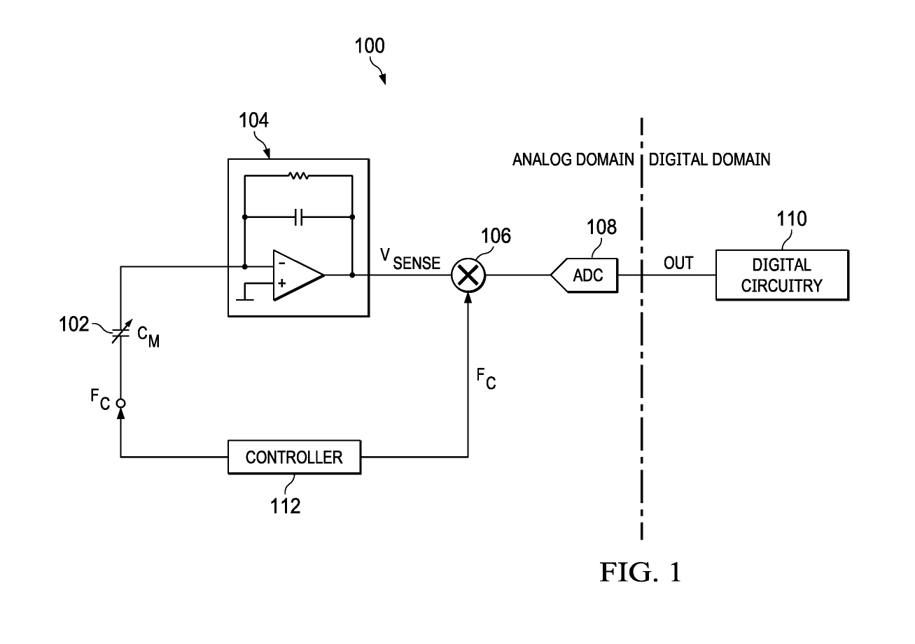

FIG. 1 is a block diagram of selected components of an example capacitance-sensing circuit 100 for sensing a variable capacitance C_{M} of a component 102, wherein carrier demodulation is implemented in an analog domain, in accordance with embodiments of the present disclosure. In some embodiments, component 102 may comprise a transducer and capacitance C_{M} may be representative of a displacement of such transducer. Examples of such a transducer may include an audio speaker, a linear resonant actuator, and a haptic transducer. However, the systems and methods disclosed herein are not limited to measuring displacement in a transducer, and may be applied to any suitable measuring or sensing of a capacitance.

As shown in FIG. 1, capacitance sensing circuit 100 may include a capacitance-to-voltage converter (CVC) 104, a demodulator 106, an analog-to-digital converter (ADC) 108, digital circuitry 110, and a controller 112. CVC 104 may comprise a charge integrator configured to integrate charge at its input to generate a voltage signal V_{SENSE} indicative of capacitance C_{M} of component 102. Such voltage signal V_{SENSE} may be generated by applying an excitation signal at a carrier frequency f_{C} to one of the terminals of capacitance C_{M} of component 102, which may cause generation of a modulated voltage signal V_{SENSE} from a baseband signal indicative of capacitance C_{M}, wherein the excitation signal is of a carrier frequency f_{C} which is higher than frequency content of the baseband signal. Demodulator 106 may demodulate modulated voltage signal V_{SENSE} at the carrier frequency f_{C} in an analog domain of capacitance sensing circuit 100 to generate an output signal representative of a capacitance of the capacitor wherein the demodulating is based, at least in part, on the excitation signal. ADC 108 may convert the demodulated analog signal into an equivalent digital output signal OUT that may be further processed by digital circuitry 110. As shown in FIG. 1, ADC 108 may define a boundary between an analog domain of a signal path of capacitance sensing circuit 100 and a digital domain of the signal path of capacitance sensing circuit 100.

Controller 112 may be configured to apply the excitation signal to one of the terminals of capacitance C_{M} of component 102 as described above. In some embodiments, such excitation signal may comprise a square-wave signal. Controller 112 may also be configured to generate the excitation signal or a similar signal to demodulator 106 such that demodulator 106 demodulates modulated voltage signal V_{SENSE} as described above. Further, controller 112 may be configured to determine whether noise in the modulated signal is caused by interference at approximately carrier frequency f_{C} of the excitation signal. Such determination may be made in any suitable manner, including, without limitation correlation of measurement by measuring a known capacitor value within an environment that may cause interference. In addition, controller 112 may be configured to, in response to determining noise in modulated voltage signal V_{SENSE} is caused by interference at approximately carrier frequency f_{C}, controller 112 may modify carrier frequency f_{C} to another frequency, such that the excitation signal to component 102 and demodulation signal to demodulator 108 are modified in accordance with the new frequency, in order to reduce noise caused in modulated voltage signal V_{SENSE} by the interference.

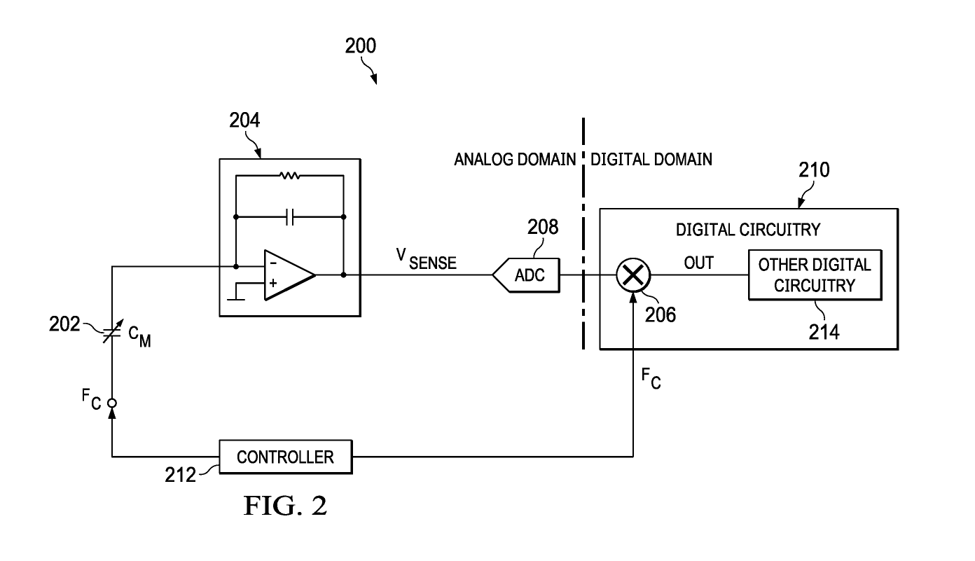

FIG. 2 is a block diagram of selected components of an example capacitance-sensing circuit 200 for sensing a variable capacitance C_{M} of a component 202, wherein carrier demodulation is implemented in a digital domain, in accordance with embodiments of the present disclosure. In some embodiments, component 202 may comprise an audio speaker and capacitance C_{M} may be representative of a displacement of an audio transducer of such audio speaker. However, the systems and methods disclosed herein are not limited to measuring displacement in an audio speaker, and may be applied to any suitable measuring or sensing of a capacitance.

As shown in FIG. 2, capacitance sensing circuit 200 may include a capacitance-to-voltage converter (CVC) 204, an analog-to-digital converter (ADC) 208, digital circuitry 210, and a controller 212. CVC 204 may comprise a charge integrator configured to integrate charge at its input to generate a voltage signal V_{SENSE} indicative of capacitance C_{M} of component 202. Such voltage signal V_{SENSE} may be generated by applying an excitation signal at a carrier frequency f_{C} to one of the terminals of capacitance C_{M} of component 202, which may cause generation of a modulated voltage signal V_{SENSE} from a baseband signal indicative of capacitance C_{M}, wherein the excitation signal is of a carrier frequency f_{C} which is higher than frequency content of the baseband signal.

ADC 208 may convert modulated voltage signal V_{SENSE} into an equivalent modulated digital signal that may be further processed by digital circuitry 210. As shown in FIG. 2, ADC 208 may define a boundary between an analog domain of a signal path of capacitance sensing circuit 200 and a digital domain of the signal path of capacitance sensing circuit 200.

As also depicted in FIG. 2, digital circuitry 210 may include a demodulator 206. Demodulator 206 may demodulate the modulated digital signal from ADC 208 at the carrier frequency f_{C} in a digital domain of capacitance sensing circuit 200 to generate a digital output signal OUT (that may be further processed by other digital circuitry 214) representative of a capacitance of the capacitor wherein the demodulating is based, at least in part, on the excitation signal. For example, the demodulation signal received by demodulator 206 may comprise a sine wave at carrier frequency f_{C}.

Controller 212 may be configured to apply the excitation signal to one of the terminals of capacitance C_{M} of component 202 as described above. In some embodiments, such excitation signal may comprise a square-wave signal. Controller 212 may also be configured to generate a digital equivalent of the excitation signal (e.g., a sine wave at carrier frequency f_{C}) to demodulator 206 such that demodulator 206 demodulates the modulated digital signal generated by ADC 208 as described above. Further, controller 212 may be configured to determine whether noise in the modulated signal is caused by interference at approximately carrier frequency f_{C} of the excitation signal. Such determination may be made in any suitable manner, including, without limitation correlation of measurement by measuring a known capacitor value within an environment that may cause interference. In addition, controller 212 may be configured to, in response to determining noise in modulated digital signal generated by ADC 208 is caused by interference at approximately carrier frequency f_{C}, controller 212 may modify carrier frequency f_{C} to another frequency, such that the excitation signal to component 202 and demodulation signal to demodulator 208 are modified in accordance with the new frequency, in order to reduce noise caused in the modulated digital signal by the interference.

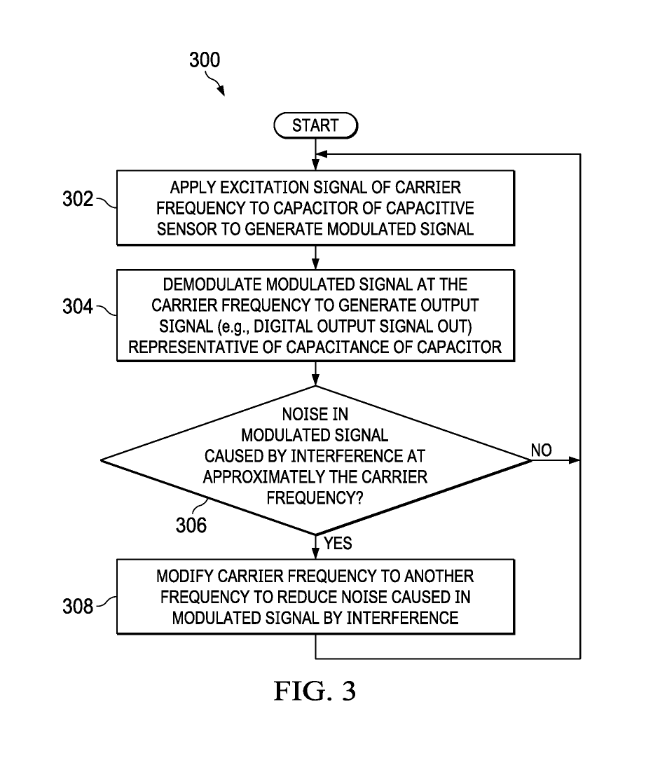

FIG. 3 is a flow chart of an example method 300 for reducing noise in a capacitive sensor, in accordance with embodiments of the present disclosure. According to certain embodiments, method 300 may begin at step 302. As noted above, teachings of the present disclosure may be implemented in a variety of configurations of a capacitive sensing circuit. As such, the preferred initialization point for method 300 and the order of the steps comprising method 300 may depend on the implementation chosen. In these and other embodiments, method 300 may be implemented as firmware, software, applications, functions, libraries, or other instructions.

At step 302, signal generator (e.g., controller 112, controller 212) may apply an excitation signal to a capacitor of a capacitive sensor (e.g., component 102, component 202) which causes generation of a modulated signal from a baseband signal, wherein the excitation signal is of a carrier frequency (e.g., carrier frequency f_{C}) which is higher than frequency content of the baseband signal. At step 304, a demodulator (e.g., demodulator 106, demodulator 206) may demodulate the modulated signal to generate an output signal (e.g., digital output signal OUT) representative of a capacitance of the capacitor wherein the demodulating is based, at least in part, on the excitation signal (e.g., at carrier frequency f_{C}). In some embodiments, the modulated signal may comprise a digital signal and demodulating the modulated signal may comprise demodulating the modulated signal in a digital domain. In other embodiments, the modulated signal may comprise an analog signal and demodulating the modulated signal may comprise demodulating the modulated signal in an analog domain.

At step 306, a controller (e.g., controller 112, controller 212) may determine whether noise in the modulated signal is caused by interference at approximately the carrier frequency (e.g., carrier frequency f_{C}). If noise in the modulated signal is caused by interference at approximately the carrier frequency, method 300 may proceed to step 308. Otherwise, method 300 may proceed again to step 302.

At step 308, in response to determining noise in the modulated signal is caused by interference at approximately the carrier frequency, the controller (e.g., controller 112, controller 212) may modify the carrier frequency to another frequency to reduce noise caused in the modulated signal by the interference. After completion of step 308, method 300 may proceed again to step 302.

Although FIG. 3 discloses a particular number of steps to be taken with respect to method 300, method 300 may be executed with greater or fewer steps than those depicted in FIG. 3. In addition, although FIG. 3 discloses a certain order of steps to be taken with respect to method 300, the steps comprising method 300 may be completed in any suitable order.

Method 300 may be implemented in whole or part using controller 112, controller 212, components thereof or any other system operable to implement method 300. In certain embodiments, method 300 may be implemented partially or fully in software and/or firmware embodied in computer-readable media.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the exemplary embodiments herein that a person having ordinary skill in the art would comprehend. Similarly, where appropriate, the appended claims encompass all changes, substitutions, variations, alterations, and modifications to the exemplary embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

All examples and conditional language recited herein are intended for pedagogical objects to aid the reader in understanding this disclosure and the concepts contributed by the inventor to furthering the art, and are construed as being without limitation to such specifically recited examples and conditions. Although embodiments of the present disclosure have been described in detail, it should be understood that various changes, substitutions, and alterations could be made hereto without departing from the spirit and scope of the disclosure.

What is claimed is:

1. A method for measuring a capacitive sensor output, comprising:
applying an excitation signal to a capacitor of the capacitive sensor which causes generation of a modulated signal from a baseband signal, wherein the excitation signal is of a carrier frequency which is higher than frequency content of the baseband signal;
demodulating the modulated signal to generate an output signal representative of a capacitance of the capacitor wherein the demodulating is based, at least in part, on the excitation signal;
determining whether noise in the modulated signal is caused by interference at approximately the carrier frequency; and
in response to determining noise in the modulated signal is caused by interference at approximately the carrier frequency, modifying the carrier frequency to another frequency to reduce noise caused in the modulated signal by the interference.

2. The method of claim 1, wherein the modulated signal is a digital signal and wherein demodulating the modulated signal comprises demodulating the modulated signal in a digital domain.

3. The method of claim 1, wherein the modulated signal is an analog signal and wherein demodulating the modulated signal comprises demodulating the modulated signal in an analog domain

4. The method of claim 1, wherein the displacement is representative of a displacement of a transducer.

5. The method of claim 4, wherein the transducer comprises one of a speaker, a linear resonant actuator, and a haptic transducer.

6. An apparatus for measuring a capacitive sensor output, comprising:
an excitation source configured to apply an excitation signal to a capacitor of the capacitive sensor which causes generation of a modulated signal from a baseband signal, wherein the excitation signal is of a carrier frequency which is higher than frequency content of the baseband signal;
a demodulator configured to demodulate the modulated signal to generate an output signal representative of a capacitance of the capacitor, wherein the demodulator is configured to demodulate based, at least in part, on the excitation signal; and
a controller configured to:
determine whether noise in the modulated signal is caused by interference at approximately the carrier frequency; and
in response to determining noise in the modulated signal is caused by interference at approximately the carrier frequency, modify the carrier frequency to another frequency to reduce noise caused in the modulated signal by the interference.

7. The apparatus of claim 6, wherein the modulated signal is a digital signal and wherein the demodulator is configured to demodulate the modulated signal by demodulating the modulated signal in a digital domain.

8. The apparatus of claim 6, wherein the modulated signal is an analog signal and wherein the demodulator is configured to demodulate the modulated signal in an analog domain.

9. The apparatus of claim 6, wherein the displacement is representative of a displacement of a transducer.

10. The apparatus of claim 9, wherein the transducer comprises one of a speaker, a linear resonant actuator, and a haptic transducer.
